(19) United States
(12) Patent Application Publication
(10) Pub. No.: US 2025/0203988 A1
(43) Pub. Date: Jun. 19, 2025

(54) LOWER GATE CAP FOR BACKSIDE CONTACT INSULATION

(71) Applicant: International Business Machines Corporation, Armonk, NY (US)

(72) Inventors: Lijuan Zou, Slingerlands, NY (US); Tao Li, Slingerlands, NY (US); Ruilong Xie, Niskayuna, NY (US); Nicolas Jean Loubet, Guilderland, NY (US)

(21) Appl. No.: 18/541,420

(22) Filed: Dec. 15, 2023

(51) Int. Cl. H01L 29/66; H01L 21/8234; H01L 27/088; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/116; H10D 62/121; H10D 84/0128; H10D 84/013; H10D 84/0149; H10D 84/038; H10D 84/83

(57) ABSTRACT

Semiconductor devices include an active part that includes a semiconductor channel and a gate stack. A frontside part includes a frontside electrical contact to the active part. A backside part includes a backside electrical contact to the active part. A lower gate cap electrically insulates the gate from the backside electrical contact and includes a first region of the lower gate cap that is in contact with a shallow trench isolation (STI) structure of the backside part and a second region of the lower gate cap that is in contact with a surface of the backside electrical contact.

### BACKGROUND

The present invention generally relates to semiconductor device fabrication and, more particularly, to semiconductor devices having backside contacts.

Transistor devices and other semiconductor devices may be formed with electrical contacts above and below the device. The formation of backside contacts may include removal of a substrate and etching through a backside dielectric layer to expose the underside of source and drain structures of the device. However, forming such backside contacts may result in over-etching that exposes a portion of the underside of the device's gate. When this happens, the backside contact may short-circuit to the gate and cause the device to fail.

### SUMMARY

A semiconductor device includes an active part that includes a semiconductor channel and a gate stack. A frontside part includes a frontside electrical contact to the active part. A backside part includes a backside electrical contact to the active part. A lower gate cap electrically insulates the gate from the backside electrical contact and includes a first region of the lower gate cap that is in contact with a shallow trench isolation (STI) structure of the backside part and a second region of the lower gate cap that is in contact with a surface of the backside electrical contact.

A semiconductor device includes an active part that includes a semiconductor channel, a gate stack, and source/drain regions in contact with the semiconductor channel. A frontside part includes a frontside electrical contact to the active part. A backside part that a backside electrical contact to a source/drain region in the active part and an STI structure formed from a first dielectric material. A lower gate cap electrically insulates the gate from the backside electrical contact, formed from a second dielectric material distinct from the first dielectric material, and includes a first region of the lower gate cap that is in contact with the shallow trench isolation (STI) structure of the backside part and a second region of the lower gate cap that is in contact with a surface of the backside electrical contact.

A semiconductor device includes an active part that includes a semiconductor channel, a gate stack, and source/drain regions in contact with the semiconductor channel. A frontside part includes a frontside electrical contact to the active part. A backside part includes a backside electrical contact to a source/drain region in the active part and a shallow trench isolation (STI) structure formed from a first dielectric material. A dielectric remnant is positioned between the backside electrical contact and the semiconductor channel. A lower gate cap electrically insulates the gate from the backside electrical contact, formed from a second dielectric material distinct from the first dielectric material. The lower gate cap includes a first region of the lower gate cap that is in contact with the STI structure of the backside part, a second region of the lower gate cap that is in contact with a surface of the backside electrical contact, and shoulders that extend vertically from a planar portion of the lower gate cap that includes the first region and the second region.

A method of forming a semiconductor device includes forming channel structures on a substrate. A shallow trench isolation (STI) layer is formed in a trench of a substrate. A dielectric lower gate cap is formed on the STI layer between channel structures. A gate stack is formed over the lower gate cap, on the channel structures. The substrate is etched away and a backside interlayer dielectric is formed. A via is etched through the backside interlayer dielectric that exposes a portion of the lower gate cap. A conductive contact is formed in the via that contacts the lower gate cap.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a semiconductor device that illustrates a set of cross-sectional planes, in accordance with an embodiment of the present invention;

FIG. 2 is a set of cross-sectional views of a step in the fabrication of a semiconductor device, illustrating the formation of nanosheet fin stacks, in accordance with an embodiment of the present invention;

FIG. 3 is a set of cross-sectional views of a step in the fabrication of a semiconductor device, illustrating the formation of a layer of cap material over nanosheet fin stacks, in accordance with an embodiment of the present invention;

FIG. 4 is a set of cross-sectional views of a step in the fabrication of a semiconductor device, illustrating the formation of a layer of protective material, in accordance with an embodiment of the present invention;

FIG. 5 is a set of cross-sectional views of a step in the fabrication of a semiconductor device, illustrating the removal of cap material from side surfaces of the nanosheet fins tacks, in accordance with an embodiment of the present invention;

FIG. 6 is a set of cross-sectional views of a step in the fabrication of a semiconductor device, illustrating the removal of the protective material and the cap material from the top of the nanosheet fin stacks, in accordance with an embodiment of the present invention;

FIG. 7 is a set of cross-sectional views of a step in the fabrication of a semiconductor device, illustrating the etch of the nanosheet fin stacks in source/drain regions, in accordance with an embodiment of the present invention;

FIG. 8 is a set of cross-sectional views of a step in the fabrication of a semiconductor device, illustrating the formation source/drain structures, in accordance with an embodiment of the present invention;

FIG. 9 is a set of cross-sectional views of a step in the fabrication of a semiconductor device, illustrating the completion of the frontside structures, in accordance with an embodiment of the present invention;

FIG. 10 is a set of cross-sectional views of a step in the fabrication of a semiconductor device, illustrating the removal of the substrate and the formation of a backside interlayer dielectric, in accordance with an embodiment of the present invention;

FIG. 11 is a set of cross-sectional views of a step in the fabrication of a semiconductor device, illustrating the formation of vias through the backside interlayer dielectric, in accordance with an embodiment of the present invention;

FIG. 12 is a set of cross-sectional views of a step in the fabrication of a semiconductor device, illustrating the completion of the backside structures, in accordance with an embodiment of the present invention;

FIG. 13 is a set of cross-sectional views of an alternative step in the fabrication of a semiconductor device, where the dielectric cap is formed without a vertical part on the sidewalls of the nanosheet fin stacks, in accordance with an embodiment of the present invention;

FIG. 14 is a set of cross-sectional views of a step in the fabrication of a semiconductor device, illustrating a completed device with a dielectric cap that lacks the vertical part on the sidewalls of the nanosheet fin stacks, in accordance with an embodiment of the present invention; and

FIG. 15 is a block/flow diagram of a method for fabricating a semiconductor device, in accordance with an embodiment of the present invention.

### DETAILED DESCRIPTION

To prevent shorting between the gate and backside electrical contacts, a lower gate cap may be formed early on in the device fabrication. This lower gate cap may be positioned in regions between semiconductor nanosheet fin stacks, such as on top of a shallow-trench isolation (STI) structure. When the substrate is later removed and replaced by a backside dielectric layer, any over-etching to the backside dielectric layer may be stopped by the lower gate cap, thereby preventing short-circuits between the gate and the backside contact.

Depending on the process used to form the lower gate cap, different cap shapes may be created. In embodiments that use a conformal deposition process for the cap material, a shield structure may be used to prevent removal of cap material at the horizontal surface between the nanosheet fin stacks. This produces a u-shaped profile for the lower gate cap. In embodiments that use a directional deposition process for the cap material, the resulting lower gate cap may have a planar profile.

A semiconductor device includes an active part that includes a semiconductor channel and a gate structure. A frontside part includes a frontside electrical contact to the active part. A backside part includes a backside electrical contact to the active part. A lower gate cap electrically insulates the gate from the backside electrical contact and includes a first region of the lower gate cap that is in contact with a shallow trench isolation (STI) structure of the backside part and a second region of the lower gate cap that is in contact with a surface of the backside electrical contact. The lower gate cap helps to prevent short circuits between backside contacts and the gate structure.

In some cases, the lower gate cap includes shoulders that extend vertically from a planar portion of the lower gate cap that includes the first region and the second region. These shoulders help to provide a more complete electrical insulation between the backside contacts and the gate structure.

In some cases, the lower gate cap includes a dielectric material that is distinct from a dielectric material of the STI structure. These differing materials make it possible to selectively etch the lower gate cap without damaging the STI structure.

In some cases, the lower gate cap is formed from a dielectric material selected from the group consisting of SiC and SiOC. The use of these materials provides etch selectivity with respect to the interlayer dielectric.

In some cases, a dielectric backside remnant between the backside electrical contact and the semiconductor channel. The dielectric backside remnant provides additional electrical insulation between the backside electrical contact and the gate structure.

In some cases, a dielectric isolation layer is positioned between the backside remnant and the semiconductor channel. The dielectric isolation layer provides additional electrical insulation between the backside electrical contact and the gate structure.

In some cases, the dielectric backside remnant is silicon dioxide and the dielectric isolation layer is silicon nitride. The use of these materials provides etch selectivity with respect to one another, simplifying the fabrication process.

In some cases, the frontside part further includes frontside back-end-of-line (BEOL) layers and the backside part further includes backside BEOL layers. The inclusion of frontside and backside BEOL layers makes it possible to provide signal and power connections to the device without crowding the interconnect structures.

In some cases, the semiconductor channel includes a plurality of vertically aligned silicon nanosheets. The use of silicon nanosheets provides good electrical properties for a field effect transistor.

A semiconductor device includes an active part that includes a semiconductor channel, a gate structure, and source/drain regions in contact with the semiconductor channel. A frontside part includes a frontside electrical contact to the active part. A backside part that a backside electrical contact to a source/drain region in the active part and an STI structure formed from a first dielectric material. A lower gate cap electrically insulates the gate from the backside electrical contact, formed from a second dielectric material distinct from the first dielectric material, and includes a first region of the lower gate cap that is in contact with the shallow trench isolation (STI) structure of the backside part and a second region of the lower gate cap that is in contact with a surface of the backside electrical contact. The lower gate cap helps to prevent short circuits between backside contacts and the gate structure.

In some cases, the lower gate cap includes shoulders that extend vertically from a planar portion of the lower gate cap that includes the first region and the second region. These shoulders help to provide a more complete electrical insulation between the backside contacts and the gate structure.

In some cases, the lower gate cap is formed from a dielectric material selected from the group consisting of SiC and SiOC. The use of these materials provides etch selectivity with respect to the interlayer dielectric.

In some cases, a dielectric backside remnant between the backside electrical contact and the semiconductor channel. The dielectric backside remnant provides additional electrical insulation between the backside electrical contact and the gate structure.

In some cases, a dielectric isolation layer is positioned between the backside remnant and the semiconductor channel. The dielectric isolation layer provides additional electrical insulation between the backside electrical contact and the gate structure.

In some cases, the dielectric backside remnant is silicon dioxide and the dielectric isolation layer is silicon nitride. The use of these materials provides etch selectivity with respect to one another, simplifying the fabrication process.

In some cases, the frontside part further includes frontside back-end-of-line (BEOL) layers and the backside part further includes backside BEOL layers. The inclusion of frontside and backside BEOL layers makes it possible to provide signal and power connections to the device without crowding the interconnect structures.

In some cases, the semiconductor channel includes a plurality of vertically aligned silicon nanosheets. The use of silicon nanosheets provides good electrical properties for a field effect transistor.

A semiconductor device includes an active part that includes a semiconductor channel, a gate structure, and source/drain regions in contact with the semiconductor channel. A frontside part includes a frontside electrical contact to the active part. A backside part includes a backside electrical contact to a source/drain region in the active part and a shallow trench isolation (STI) structure formed from a first dielectric material. A dielectric remnant is positioned between the backside electrical contact and the semiconductor channel. A lower gate cap electrically insulates the gate from the backside electrical contact, formed from a second dielectric material distinct from the first dielectric material. The lower gate cap includes a first region of the lower gate cap that is in contact with the STI structure of the backside part, a second region of the lower gate cap that is in contact with a surface of the backside electrical contact, and shoulders that extend vertically from a planar portion of the lower gate cap that includes the first region and the second region.

In some cases, a dielectric isolation layer is positioned between the backside remnant and the semiconductor channel. The dielectric isolation layer provides additional electrical insulation between the backside electrical contact and the gate structure.

In some cases, the dielectric backside remnant is silicon dioxide and the dielectric isolation layer is silicon nitride. The use of these materials provides etch selectivity with respect to one another, simplifying the fabrication process.

A method of forming a semiconductor device includes forming channel structures on a substrate. A shallow trench isolation (STI) layer is formed in a trench of a substrate. A dielectric lower gate cap is formed on the STI layer between channel structures. A gate structure is formed over the lower gate cap, on the channel structures. The substrate is etched away and a backside interlayer dielectric is formed. A via is etched through the backside interlayer dielectric that exposes a portion of the lower gate cap. A conductive contact is formed in the via that contacts the lower gate cap. The formation of the lower gate cap prevents over-etching during backside processing from creating short circuits between the backside contacts and the gate structure.

In some cases, forming the lower gate cap includes conformally depositing a dielectric material, forming a protective structure with a directional deposition process, isotropically etching away portions of the dielectric material that are not protected by the protective structure to form a lower gate cap having shoulders that extend vertically from a planar portion of the lower gate cap, and etching away the protective structure to expose the lower gate cap. The formation of lower gate cap that includes shoulders improves electrical isolation between the backside contacts and the gate structure.

In some cases, forming the lower gate cap includes a directional deposition of dielectric material. The use of a directional deposition provides a streamlined process flow for forming the dielectric cap.

In some cases, a placeholder structure is formed in the substrate before forming the gate structure. The placeholder structure provides for self-aligned formation of backside contacts without having to precisely align a backside etch with frontside structures.

In some cases, etching the via includes etching away the placeholder structure. By etching away the placeholder structure during backside processing, the via can be opened with exact placement.

In some cases, etching the via leaves a backside dielectric remnant on under the gate structure. The backside dielectric remnant improves electrical insulation between the backside contact and the gate structure. In some cases, source/drain structures are formed at ends of the channel structures after forming the lower gate cap. This makes it possible to form the lower gate cap without the source/drain structures getting in the way.

In some cases, forming the channel structures includes forming a stack of semiconductor layers, including layers of semiconductor channel material, first sacrificial layers, and a second sacrificial layer. The use of stacked semiconductor layers provides a straightforward means for producing nanosheet semiconductor channels.

In some cases, the second sacrificial layer is etched away after forming the lower gate cap. This order of processing makes it possible to form a self-aligned substrate isolation layer.

In some cases, a self-aligned substrate isolation layer is deposited after etching away the second sacrificial layer. The self-aligned substrate isolation layer provides additional electrical insulation between the backside contacts and the gate structure.

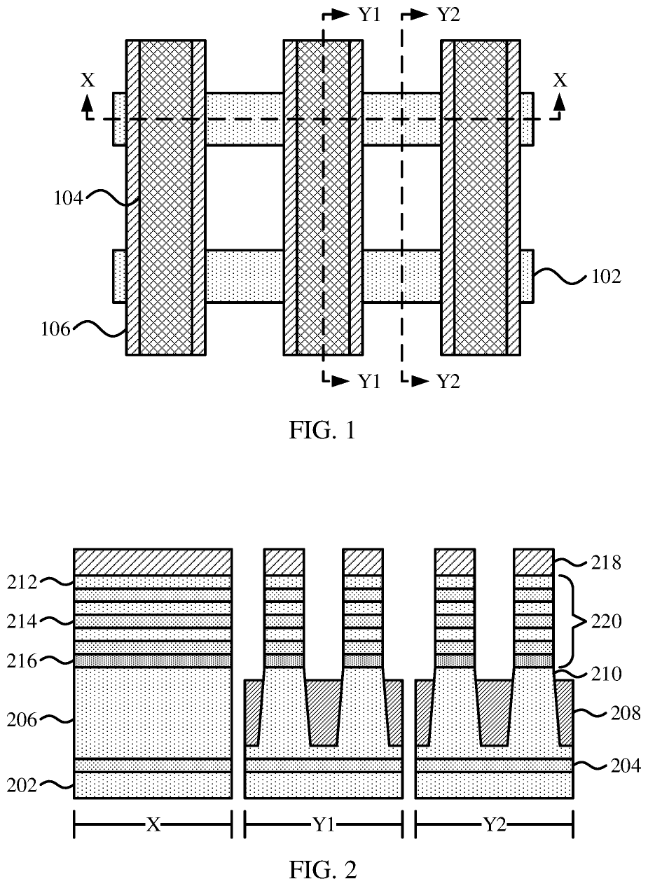

Referring now to FIG. 1, a top-down view of an intermediate step in the fabrication of a semiconductor device is shown, contrasting different cross-sectional planes that will be described in greater detail below. The device includes semiconductor channel nanosheets 102. In some embodiments, the channel nanosheets 102 may include vertically stacked nanosheet channel structures. Gates 104 crosses over the channel nanosheets 102, with gate sidewall spacers 106 insulating the gate 104 from other conductive structures.

Three cross-sectional planes are illustrated, including X, Y1, and Y2. The X plane cuts vertically and lengthwise through channel nanosheets 102. The Y1 plane cuts vertically and lengthwise through the gate 104, while the Y2 plane cuts vertically through the space between adjacent gates 104.

Referring now to FIG. 2, a set of cross-sectional views is shown of a step in the fabrication of a semiconductor device. An etch stop layer 204 is formed on a semiconductor substrate 202. The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The etch stop layer 204 may be formed from a distinct and selectively etchable material with respect to the semiconductor substrate, such as silicon germanium.

The etch stop layer may be epitaxially grown from the top surface of the semiconductor substrate 202. The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

A semiconductor fin layer 206 may be formed on a top surface of the etch stop layer 204, for example by epitaxial growth of silicon. A stack of semiconductor layers 220 may be formed on the semiconductor fin layer 206, for example using successive epitaxial growth processes. The stack 220 may include channel layers 212 of a semiconductor channel material, first sacrificial layers 214 of a second semiconductor material, and a second sacrificial layer 216 of a third semiconductor material. In some embodiments, the semiconductor channel material may be silicon, the second semiconductor material may be silicon germanium with a first germanium concentration, and the third semiconductor material may be silicon germanium with a second germanium concentration that is higher than the first germanium concentration. In one example the first germanium concentration may be about 30% and the second germanium concentration may be about 60%, but it should be understood that any appropriate concentrations may be selected to provide appropriate etch selectivity between the layers of the stack 220.

Although the channel of the present embodiments is described as being a set of vertically aligned nanosheets, it should be understood that any appropriate channel structure may be used instead. For example, nanowire channels may be used instead of nanosheets, or alternatively a whole fin may be used instead.

A hardmask 218 is formed on the stack 220, for example using photolithography and a selective etch. A layer of hardmask material, such as silicon nitride, may be deposited over the stack 220. A pattern may be produced by applying a photoresist to the surface to be etched, exposing the photoresist to a pattern of radiation, and then developing the pattern into the photoresist utilizing a resist developer. Once the patterning of the photoresist is completed, the sections of hardmask material that are covered by the photoresist are protected while the exposed regions are removed using a selective etching process. As used herein, the term “selective” in reference to a material removal process denotes that the rate of material removal for a first material is greater than the rate of removal for at least another material of the structure to which the material removal process is being applied.

After the formation of the hardmask 218, exposed portions of the stack 220 may be etched away using an anisotropic etching process. The etch may penetrate into the semiconductor fin layer 206. An exemplary anisotropic etch may include a reactive ion etch (RIE), which is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation. This forms fins 210 in the stack 220 and in the semiconductor fin layer 206.

STI structures 208 are formed in the gap between the fins. The STI structures may be formed from a dielectric material, such as silicon dioxide, using a flowable chemical vapor deposition (CVD) process. Other deposition processes include a physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

The STI structures 208 may be formed by depositing an STI material and then etching the material back to an appropriate height. As shown in FIG. 2, the height of the STI structures 208 may be lower than a height of a top surface of the fin dielectric layer 206. The etching back of the STI material may include any appropriate isotropic or anisotropic etch that selectively removes STI material without substantially harming the fins 210.

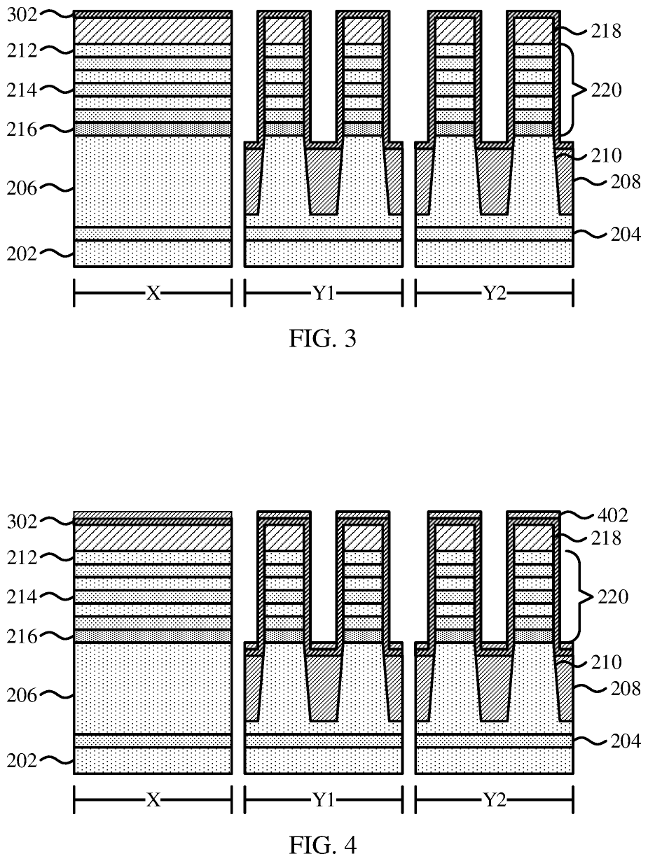

Referring now to FIG. 3, a set of cross-sectional views is shown of a step in the fabrication of a semiconductor device. In this embodiment, a cap layer 302 is conformally deposited over the fins 210 and the STI structures 208. The cap material may be any dielectric material that has etch selectivity with respect to the material of the STI structures 208. Exemplary cap materials include SiC and SiCO, deposited using a CVD or ALD process. The cap layer 302 may be formed to an exemplary thickness of about 10 nm to about 20 nm.

Referring now to FIG. 4, a set of cross-sectional views is shown of a step in the fabrication of a semiconductor device. A layer of protective material 402 is conformally deposited over the cap layer 302. The protective material may have etch selectivity with the cap material and, in some particular embodiments, may be formed from silicon dioxide using a CVD or ALD process to an exemplary thickness of about 10 nm.

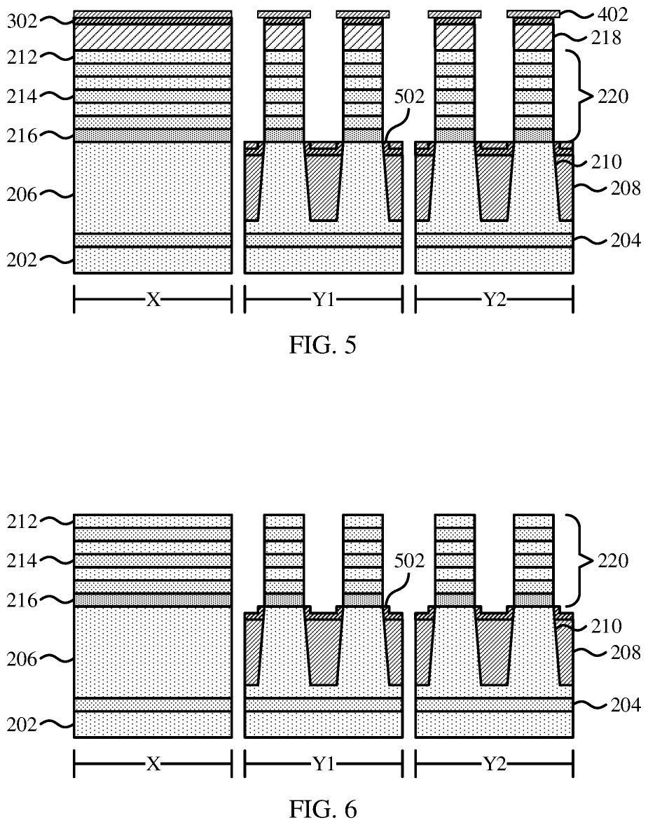

Referring now to FIG. 5, a set of cross-sectional views is shown of a step in the fabrication of a semiconductor device. An isotropic etch, such as a wet or dry chemical etch, is used to selectively remove exposed portions of the cap layer 302, leaving behind caps 502 in areas that are protected by the layer of protective material 402. In some embodiments, the caps 502 may have a shoulder portion that extends upward along sidewalls of the fins 210.

Referring now to FIG. 6, a set of cross-sectional views is shown of a step in the fabrication of a semiconductor device. The layer of protective material 402 is selectively etched away, and the hardmask 218 may be removed by, e.g., a chemical mechanical planarization (CMP) to expose the top of the stack 220. CMP is performed using, e.g., a chemical or granular slurry and mechanical force to gradually remove upper layers of the device. The slurry may be formulated to be unable to dissolve, for example, the semiconductor materials of the stack 220, resulting in the CMP process's inability to proceed any farther. An organic planarizing layer (OPL) may be used during this process to protect the caps 502, and may subsequently be removed.

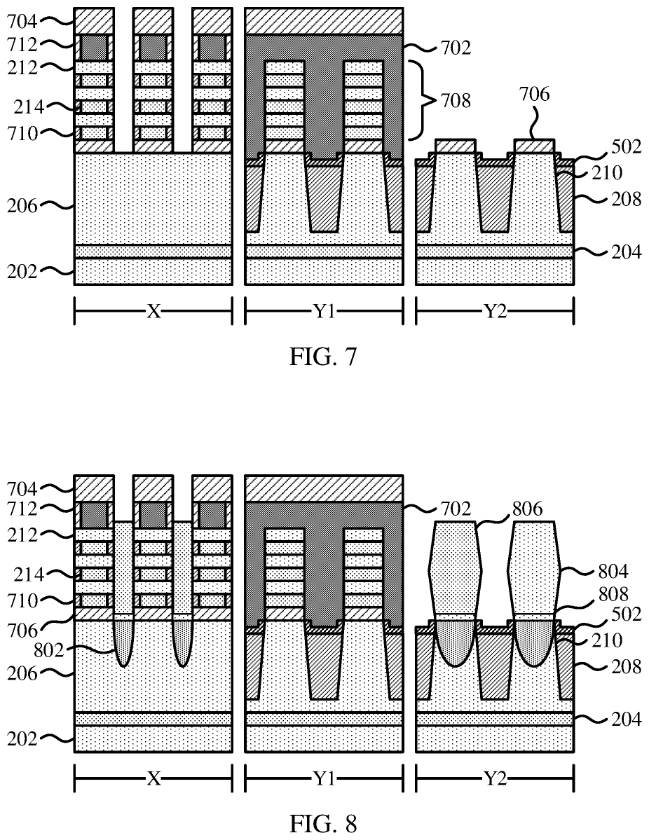

Referring now to FIG. 7, a set of cross-sectional views is shown of a step in the fabrication of a semiconductor device. The second sacrificial layer 216 may be etched away and may be replaced by a self-aligned substrate isolation layer 706 using a conformal deposition of, e.g., silicon nitride, that fills in the gap underneath the stack of semiconductor layers left by the removal of the second sacrificial layer 216.

A layer of dummy gate material, such as polysilicon, is deposited over the fins 210 using any appropriate deposition process. A gate hardmask 704 may be formed from any appropriate hardmask material, such as silicon nitride, and may be patterned to define gate regions. The dummy gate material and the stacks 220 may then be anisotropically etched using, e.g., one or more selective RIE processes, leaving behind dummy gates 702 and etched semiconductor stacks 708. Gate sidewall spacers 712 may be formed using, e.g., a conformal deposition of silicon nitride. The presence of the caps 502 prevent over-etching into the STI structures 208, which helps to prevent damage to the fins 210.

As shown in cross-section Y2, portions of the stack 220 that are not protected by the gate hardmask 704 may be removed completely, exposing the isolation layer 706. As shown in cross-section X, exposed portions of the first sacrificial layer 214 may be recessed and inner spacers 710 may be formed from, e.g., silicon dioxide. In some embodiments, the first sacrificial layers 214 may be selectively and isotropically etched. In some embodiments, the first sacrificial layers 214 may be oxidized with a process that selectively affects the material of the first sacrificial layers 214 to form silicon dioxide on the ends, while driving germanium deeper into the first sacrificial layers 214.

Referring now to FIG. 8, a set of cross-sectional views is shown of a step in the fabrication of a semiconductor device. Exposed portions of the isolation layer 706 are removed using any appropriately selective etch. This exposes the top surface of the semiconductor fin layer 206. The top surface of the semiconductor fin layer 206 may be anisotropically etched and a placeholder structure 802 may be formed in the resulting gap, being formed from silicon germanium or any other material with appropriate etch selectivity.

Source and drain regions 804/806 are then epitaxially grown, for example from exposed edges of the semiconductor channel layers 212. A buffer silicon layer 808 may be used to improve uniformity of the epitaxial growth. Respective areas may be masked while the semiconductor material is epitaxially grown in the other area, so that in some embodiments the regions may be differently doped. For example, some regions 804 may be doped with a p-type dopant, and other regions 806 may be doped with an n-type dopant. The regions may have different respective semiconductor materials as well, such as silicon and silicon germanium.

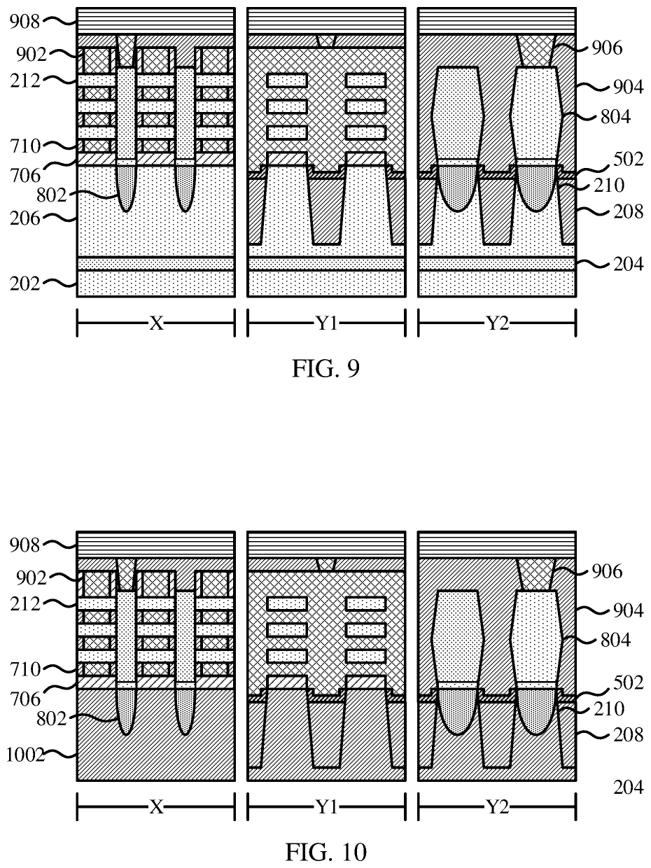

Referring now to FIG. 9, a set of cross-sectional views is shown of a step in the fabrication of a semiconductor device. The gate hardmask 704 and dummy gate 702 are etched away, exposing the stack 708 of semiconductor layers. The caps 502 further protect the STI structures 208 from damage during the etch of the dummy gate 702.

The first sacrificial layers 214 are selectively etched away, leaving the semiconductor channel layers 212 suspended. A gate stack 902 is formed over and around the semiconductor channel layers 212, including a gate dielectric layer and a gate structure, and optionally including a work function metal layer. An interlayer dielectric 904 is deposited over and around the gate stack 902 and source/drain regions 804, for example depositing silicon dioxide using a CVD process.

Conductive contacts 906 may be formed in the interlayer dielectric 904, for example by patterning vias through the interlayer dielectric 904 and filling the vias with conductive material. The contacts 906 may make contact with source/drain regions 804 and/or the gate stack 902. One or more BEOL layers 908 may be formed over the interlayer dielectric 904 and may electrically connect to the conductive contacts 906. The BEOL layers may include signal-and power-transporting conductive lines.

The conductive material of the gate stack 902 may include any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate structure may alternatively be formed from a doped semiconductor material such as, e.g., doped polysilicon. The conductive contacts 906 may similarly be formed from any appropriate conductive metal.

The gate dielectric of the gate stack 902 may include a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

At this stage, a carrier wafer may be bonded to the BEOL layers 908 for handling. The entire structure may be turned upside-down to expose the semiconductor substrate 202 for further processing and for the formation of backside structures.

Referring now to FIG. 10, a set of cross-sectional views is shown of a step in the fabrication of a semiconductor device. The semiconductor substrate 202 is etched away, for example using a selective etch that stops on the etch stop layer 204. The etch stop layer 204 may also be removed, along with the semiconductor fin layer 206, exposing the placeholder structures 802, the isolation layers 706, and the STI structures 208. A backside interlayer dielectric 1002 is deposited, for example as silicon dioxide using a CVD process. The backside interlayer dielectric 1002 covers the placeholder structures 802 and the STI structures 208. Hereinafter the backside interlayer dielectric 1002 and the STI structures 208 are shown as a single layer 1002 for convenience.

Referring now to FIG. 11, a set of cross-sectional views is shown of a step in the fabrication of a semiconductor device. Vias 1102 are etched into the backside interlayer dielectric 1002 to expose a placeholder structure 802. Any appropriate photolithographic masking and anisotropic etch may be used to form the vias 1102. The caps 502 prevent the via 1102 from exposing a portion of the gate stack 902. A remnant portion of dielectric material may remain in the via 1102, for example as shown in cross-section X, underneath the isolation layer 706.

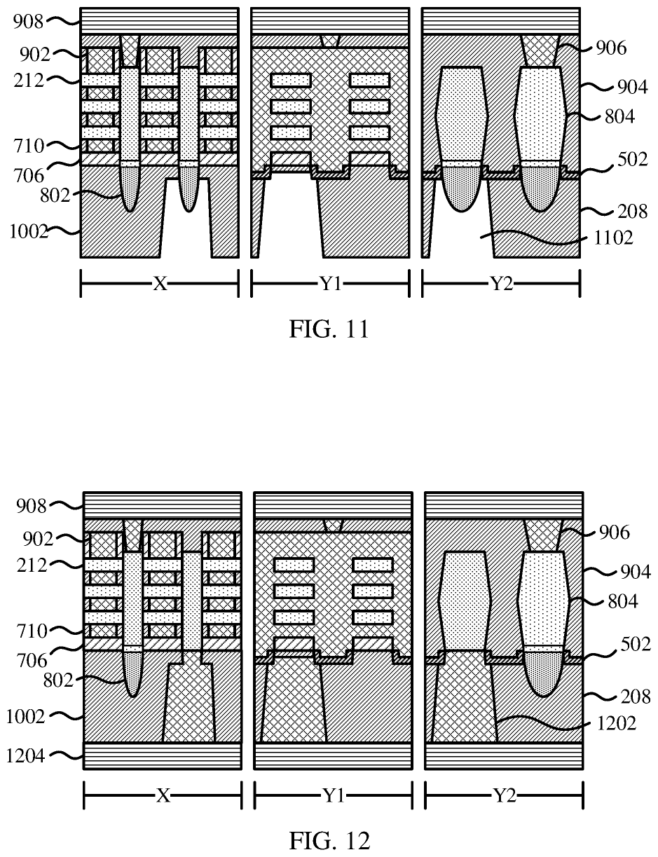

Referring now to FIG. 12, a set of cross-sectional views is shown of a step in the fabrication of a semiconductor device. The exposed placeholder structure 802 in the via 1102 is etched away, exposing the underside of, e.g., a source/drain region 804. The via 1102 is filled with a conductive material to form backside contact 1202. A CMP process may be performed to remove conductive material from surfaces outside the via 1102 and backside BEOL layers 1204 may be formed, for example including a backside power rail and any other appropriate signal- or power-carrying lines.

The device may be viewed as having three principal parts: an active part that includes the semiconductor channel layers 212 and the gate stack 902, a frontside part that includes electrical contacts to the active layer from a first side of the active layer, and a backside part that includes electrical contacts to the active part from a second side of the active layer. The lower gate caps are formed between the active part and the backside part.

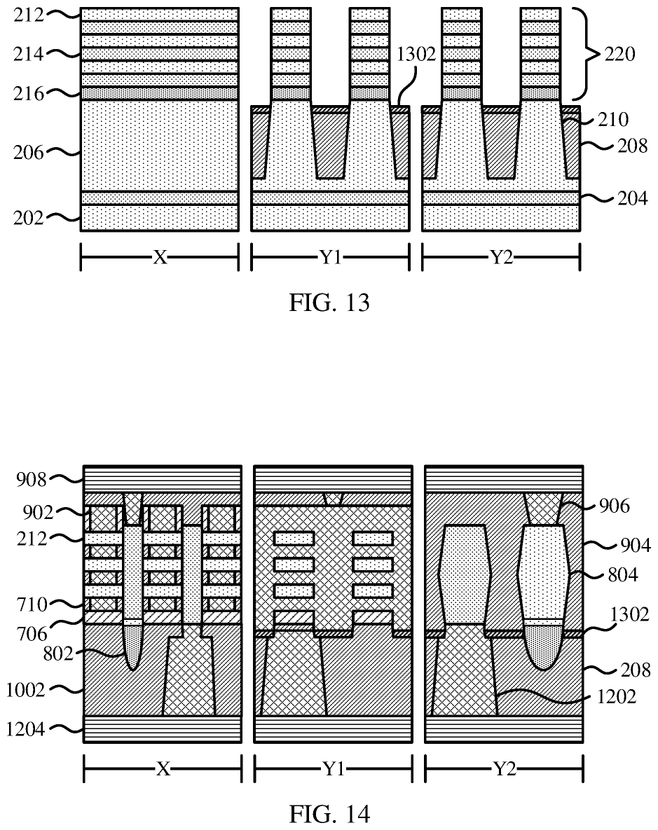

Referring now to FIG. 13, a set of cross-sectional views is shown of a step in the fabrication of a semiconductor device. This view corresponds to that shown in FIG. 6 above, but shows a different embodiment of the lower gate cap. Instead of having a u-shaped profile, with shoulders along the vertical sidewalls of the fins 210, this embodiment of the caps 1302 has a flat top surface. The cap may be formed by a directional deposit of cap material, for example using a high density plasma deposition or GCIB deposition.

Referring now to FIG. 14, a set of cross-sectional views is shown of a step in the fabrication of a semiconductor device. This view shows the finished device with the flat-topped caps 1302 formed by directional deposition.

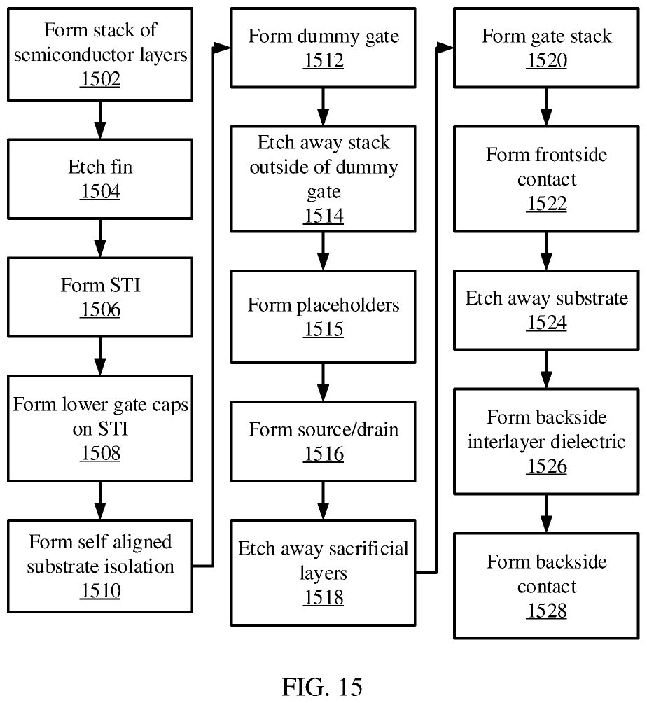

Referring now to FIG. 15, a method of fabricating a semiconductor device is shown. Block 1502 forms a stack of semiconductor layers 220 on the semiconductor fin layer 206. The stack may be formed by successive epitaxial growth processes with different materials, for example using a silicon for the channel layers 212, silicon germanium with a first germanium concentration for the first sacrificial layers 214, and silicon germanium with a second germanium concentration for the second sacrificial layers 216. The layers may be grown to a thickness below a threshold value at which discontinuities being to form due to small differences in the crystalline structure.

Block 1504 etches fins 210 into the stack 220 and into the semiconductor fin layer 206. The fins' shape may be defined by the photolithographic patterning of a hardmask 218 from a hardmask material, such as silicon nitride. An anisotropic etch may be used. Block 1506 then forms STI structures 208 in the trenches of the semiconductor fin layer 206, for example using a flowable CVD of silicon dioxide.

Block 1508 forms the lower gate caps. In some embodiments, cap material may be conformally deposited and then covered on horizontal surfaces by directional deposition of a protective material. In such embodiments, exposed portions of the cap material may be isotropically etched away, while the protective material preserves covered parts of the cap material, resulting in caps 502 that have a shoulder portion on vertical sidewall surfaces of the stacks 220. In other embodiments, the cap material may be formed with a directional deposition, resulting in caps 1302 that lack the vertical shoulder portions.

Block 1510 forms a self-aligned substrate isolation layer 706, for example by selectively etching away the second sacrificial layer 216 and conformally depositing dielectric material to fill the space left by removal of the second sacrificial layer 216. A selective anisotropic etch may be used to remove excess dielectric material from regions that are not protected by the stack 220. Block 1512 may then form dummy gates 702 over the fins 210, for example by depositing a dummy gate material and patterning it using a dummy gate hardmask 704. Block 1514 anisotropically etches away the stack around the dummy gate hardmask 704, establishing a channel region. Additional steps at this point may include the formation of inner spacers 710, for example by oxidizing exposed ends of the first sacrificial layers 214 or my recessing the first sacrificial layers 214 and conformally depositing dielectric material in the recesses.

Block 1515 forms placeholder structures 802. An anisotropic etch may be performed to remove material from the semiconductor fin layer 206 between the channel regions, and the resulting gap may be filled with any material having appropriate etch selectivity. Block 1516 forms source/drain regions, for example by epitaxially growing doped semiconductor material from exposed end surfaces of the semiconductor channel layers 212. An n-type or p-type dopant may be added in situ during the epitaxial growth.

Block 1518 etches away the first sacrificial layers 214 using an isotropic etch that leaves the semiconductor channel layers 212 suspended. Block 1520 then forms the gate stack 902 around and between the semiconductor channel layers 212, including the conformal deposition of a high-k gate dielectric layer and a gate structure.

Block 1522 forms frontside contacts 906, for example by forming a frontside interlayer dielectric 904, patterning the frontside interlayer dielectric 904 to form vias, depositing a conductive material to fill the vias, and removing excess material on a top surface of the frontside interlayer dielectric 904 using a CMP process.

Block 1524 etches away the semiconductor substrate 202, the etch stop layer 204, and the remaining parts of the semiconductor fin layer 206 using, for example, a series of selective etches.

Block 1526 forms a backside interlayer dielectric 1002 and block 1528 forms backside contacts 1202 through the backside interlayer dielectric 1002. Block 1528 may form vias 1102 in the backside dielectric layer using an anisotropic etch, where the lower gate caps prevent over-etching of the vias that could otherwise expose the underside of the gate stack 902. Block 1528 may then deposit conductive material in the vias 1102 to form the contacts 1202, with a CMP process removing conductive material from the horizontal surfaces of the backside interlayer dielectric 1002.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SixGe1-x where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising.” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper.” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a lower gate cap for backside contact insulation (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
an active part that includes a semiconductor channel and a gate structure;
a frontside part that includes a frontside electrical contact to the active part;
a backside part that includes a backside electrical contact to the active part; and
a lower gate cap that electrically insulates the gate structure from the backside electrical contact, including a first region of the lower gate cap that is in contact with a shallow trench isolation (STI) structure of the backside part and a second region of the lower gate cap that is in contact with a surface of the backside electrical contact.

2. The semiconductor device of claim 1, wherein the lower gate cap includes shoulders that extend vertically from a planar portion of the lower gate cap that includes the first region and the second region.

3. The semiconductor device of claim 1, wherein the lower gate cap includes a dielectric material that is distinct from a dielectric material of the STI structure.

4. The semiconductor device of claim 3, wherein the lower gate cap is formed from a dielectric material selected from the group consisting of SiC and SiOC.

5. The semiconductor device of claim 1, further comprising a dielectric backside remnant between the backside electrical contact and the semiconductor channel.

6. The semiconductor device of claim 5, further comprising a dielectric isolation layer between the backside remnant and the semiconductor channel.

7. The semiconductor device of claim 6, wherein the dielectric backside remnant is silicon dioxide and the dielectric isolation layer is silicon nitride.

8. The semiconductor device of claim 1, wherein the frontside part further includes frontside back-end-of-line (BEOL) layers and the backside part further includes backside BEOL layers.

9. The semiconductor device of claim 1, wherein the semiconductor channel includes a plurality of vertically aligned silicon nanosheets.

10. A semiconductor device, comprising:
an active part that includes a semiconductor channel, a gate structure, and source/drain regions in contact with the semiconductor channel;
a frontside part that includes a frontside electrical contact to the active part;
a backside part that includes a backside electrical contact to one of the source/drain regions in the active part and a shallow trench isolation (STI) structure formed from a first dielectric material; and
a lower gate cap that electrically insulates the gate structure from the backside electrical contact, formed from a second dielectric material distinct from the first dielectric material, that includes a first region of the lower gate cap that is in contact with the STI structure of the backside part and a second region of the lower gate cap that is in contact with a surface of the backside electrical contact.

11. The semiconductor device of claim 10, wherein the lower gate cap includes shoulders that extend vertically from a planar portion of the lower gate cap that includes the first region and the second region.

12. The semiconductor device of claim 10, wherein the lower gate cap is formed from a dielectric material selected from the group consisting of SiC and SiOC.

13. The semiconductor device of claim 10, further comprising a dielectric backside remnant between the backside electrical contact and the semiconductor channel.

14. The semiconductor device of claim 13, further comprising a dielectric isolation layer between the backside remnant and the semiconductor channel.

15. The semiconductor device of claim 14, wherein the dielectric backside remnant is silicon dioxide and the dielectric isolation layer is silicon nitride.

16. The semiconductor device of claim 10, wherein the frontside part further includes frontside back-end-of-line (BEOL) layers and the backside part further includes backside BEOL layers.

17. The semiconductor device of claim 10, wherein the semiconductor channel includes a plurality of vertically aligned silicon nanosheets.

18. A semiconductor device, comprising:
an active part that includes a semiconductor channel, a gate structure, and source/drain regions in contact with the semiconductor channel;
a frontside part that includes a frontside electrical contact to the active part;
a backside part that includes a backside electrical contact to one of the source/drain regions in the active part and a shallow trench isolation (STI) structure formed from a first dielectric material;
a dielectric remnant between the backside electrical contact and the semiconductor channel; and
a lower gate cap that electrically insulates the gate structure from the backside electrical contact, formed from a second dielectric material distinct from the first dielectric material, that includes a first region of the lower gate cap that is in contact with the STI structure of the backside part, a second region of the lower gate cap that is in contact with a surface of the backside electrical contact, and shoulders that extend vertically from a planar portion of the lower gate cap that includes the first region and the second region.

19. The semiconductor device of claim 18, further comprising a dielectric isolation layer between the backside remnant and the semiconductor channel.

20. The semiconductor device of claim 19, wherein the dielectric backside remnant is silicon dioxide and the dielectric isolation layer is silicon nitride.
